(19) United States
(12) Patent Application Publication
(10) Pub. No.: US 2026/0050340 A1
(43) Pub. Date: Feb. 19, 2026

(54) DISPLAY DEVICE

(71) Applicant: LG DISPLAY CO., LTD., SEOUL (KR)

(72) Inventors: Hyangmyoung Gwon, Paju-si (KR); JiHyun Jung, Paju-si (KR); JaeGyun Lee, Paju-si, Gyeonggi-do (KR); Ruda Rhe, Paju-si (KR)

(21) Appl. No.: 19/273,648

(22) Filed: Jul. 18, 2025

(30) Foreign Application Priority Data
Aug. 13, 2024 (KR) 10-2024-0108308

(51) Int. Cl. G06F 3/041; G06F 3/044; H10K 59/131; H10K 59/40

(52) U.S. Cl. CPC G06F 3/04164; G06F 3/0412; G06F 3/0446; H10K 59/131; H10K 59/40; G06F 2203/04107; G06F 2203/04111

(57) ABSTRACT

Implementations of the disclosure describe a display device with a substrate having a display area and a non-display area. A plurality of touch routing lines and a base voltage line are disposed in the non-display area. The base voltage line crosses the plurality of touch routing lines at a crossing position and subsequently branches into first and second branched portions. In a region extending from the crossing position, the plurality of touch routing lines is disposed between the first and second branched portions without overlapping them. This non-overlapping arrangement enables a more compact wiring layout, which can reduce the size of the non-display area, such as a bezel of the display device.

### CROSS-REFERENCE TO RELATED APPLICATION

Pursuant to 35 U.S. C. § 119(a), this application claims the benefit of an earlier filing date and right of priority to Korean Patent Application No. 10-2024-0108308, filed on Aug. 13, 2024, the contents of which are hereby incorporated by reference in their entirety.

### TECHNICAL FIELD

The present disclosure relates generally to a display device.

### BACKGROUND

As the information society develops, demand for display devices for displaying images is increasing in various forms. Various display devices, such as liquid crystal display devices and organic light emitting display devices, are being utilized in recent years.

The display device may include a display panel. The display panel may include a display area where an image is displayed, and a non-display area which is an area outside the display area. A plurality of lines may be disposed in the non-display area.

### SUMMARY

According to an aspect of the present disclosure, a display device is capable of efficiently arranging lines by minimizing the overlapping area between touch routing line areas and base voltage line areas. Configurations described herein may reduce the non-display area of the display device in a manner that improves upon challenges associated with designing lines to be disposed in the non-display area. For example, a display device may reduce the size of a non-display area by minimizing the area where touch routing line areas and a base voltage line area overlap. In other examples, a display device provides low-power driving by efficiently arranging lines.

Implementations of the disclosure may provide a display device comprising a substrate including a display area and a non-display area, the non-display area including a pad area, a plurality of touch routing lines extending in a first direction from the pad area toward the display area, and a base voltage line crossing the plurality of touch routing lines and extending in the first direction from an position crossing the plurality of touch routing lines without overlapping the plurality of touch routing lines.

Implementations of the disclosure may provide a display device comprising a substrate including a display area and a pad area of a non-display area, a first metal pattern disposed on the substrate and extending in a first direction from the pad area toward the display area, to be branched into two lines, and a second metal pattern disposed on the first metal pattern and extending in the first direction while at least partially overlapping the first metal pattern.

According to implementations of the disclosure, there may be provided a display device capable of efficiently arranging lines by minimizing the overlapping area between touch routing line areas and base voltage line areas.

According to implementations of the disclosure, there may be provided a display device capable of reducing the size of a non-display area by minimizing the area where touch routing line areas and a base voltage line area overlap.

According to implementations of the disclosure, there may be provided a display device capable of low-power driving by efficiently arranging lines. A detailed description thereof is given below.

### BRIEF DESCRIPTION OF THE DRAWINGS

The accompanying drawings, which are included to provide a further understanding of the disclosure and are incorporated in and constitute a part of this application, illustrate implementations of the disclosure and together with the description serve to explain the principle of the disclosure. In the drawings:

FIG. 1 is a plan view illustrating a configuration of a display device according to implementations of the disclosure;

FIG. 2 is a view illustrating a display panel according to an implementation of the disclosure;

FIG. 3 is a view illustrating a substrate of a display panel according to implementations of the disclosure;

FIG. 4 is a cross-sectional view illustrating a display area of a display panel according to implementations of the disclosure;

FIG. 5 is a view illustrating components for touch sensing according to implementations of the disclosure;

FIG. 6 is a view illustrating a non-display area of a display panel according to implementations of the disclosure;

FIG. 7 is a view illustrating a non-display area of a display panel according to implementations of the disclosure;

FIG. 8 is a cross-sectional view of area A1-A2 of FIG. 7;

FIG. 9 is a cross-sectional view of area B1-B2 of FIG. 7;

FIGS. 10 and 11 are cross-sectional views of area C1-C2 illustrated in FIG. 7; and

FIGS. 12 and 13 are cross-sectional views of area D1-D2 illustrated in FIG. 7.

### DETAILED DESCRIPTION

Implementations of the disclosure relate to display devices, and more particularly, to a wiring architecture within a non-display area of a display device that enables a reduction in the non-display area's size. As the non-display area, or bezel, of a display device is reduced, the density of wiring, such as touch routing lines and power lines, increases. This can lead to challenges such as signal interference from parasitic capacitance caused by overlapping lines and physical difficulty in routing the lines within the limited space.

Accordingly, implementations disclosed herein provide a display device with an improved wiring structure that addresses these challenges. In various implementations, a base voltage line is configured to cross a plurality of touch routing lines at a crossing position. Subsequent to the crossing position, the base voltage line branches into two separate portions. The plurality of touch routing lines are then disposed in a region between the two branched portions of the base voltage line, thereby avoiding overlap in the area where the lines run parallel. This non-overlapping arrangement allows for a more compact and efficient layout of the wiring, which facilitates a reduction in the width of the non-display area. Furthermore, by minimizing the overlap between the base voltage line and the touch routing lines, parasitic capacitance may be reduced, which can contribute to improved signal integrity and potentially lower power consumption.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

In the following description of examples or implementations of the disclosure, reference will be made to the accompanying drawings in which it is shown by way of illustration specific examples or implementations that can be implemented, and in which the same reference numerals and signs can be used to designate the same or like components even when they are shown in different accompanying drawings from one another. Further, in the following description of examples or implementations of the disclosure, detailed descriptions of well-known functions and components incorporated herein will be omitted when it is determined that the description may make the subject matter in some implementations of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various implementations of the disclosure are described in detail with reference to the accompanying drawings.

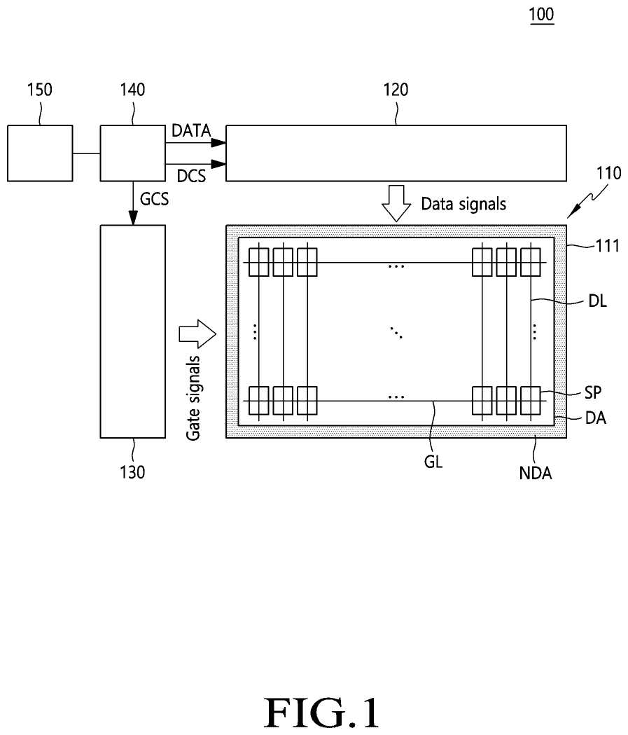

FIG. 1 is a view illustrating a system configuration of a display device 100 according to implementations of the disclosure.

Referring to FIG. 1, a display device 100 according to implementations of the disclosure may include a display panel 110 and display driving circuits, as components for displaying images. The display driving circuits are circuits for driving the display panel 110 and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA positioned outside the display area DA.

A plurality of subpixels SP for image displaying may be disposed in the display area DA, and the non-display area NDA may include a pad area PA positioned in a first direction from the display area DA.

In the display panel 110 according to implementations of the disclosure, the non-display area NDA may be very small. In some implementations of the disclosure, the non-display area NDA is also referred to as a “bezel.”

For example, the non-display area NDA may include a first non-display area positioned outside the display area DA in a first direction, a second non-display area positioned outside the display area DA in a second direction crossing the first direction, a third non-display area positioned outside the display area DA in a direction opposite to the first direction, and a fourth non-display area positioned outside the display area DA in a direction opposite to the second direction. One or two of the first to fourth non-display areas may include a pad area where the data driving circuit 120 is connected or bonded. Two or three of the first to fourth non-display areas where the pad area is not included may be very small.

As another example, the boundary area between the display area DA and the non-display area NDA may be bent so that the non-display area NDA may be positioned under the display area. In this case, no or little change may be made to the non-display area NDA shown to the user when the user views the display area 100 from the front.

Various types of signal lines for driving a plurality of subpixels SP may be disposed on the substrate 111 of the display panel 110.

The display device 100 according to implementations of the disclosure may be a liquid crystal display device or a self-emission display device in which the display panel 110 emits light by itself. When the display device 100 according to the implementations of the disclosure is a self-emission display device, each of the plurality of subpixels SP may include a light emitting element.

For example, the display device 100 according to implementations of the disclosure may be an organic light emitting diode display in which the light emitting element is implemented as an organic light emitting diode (OLED). As another example, the display device 100 according to implementations of the disclosure may be an inorganic light emitting display device in which the light emitting element is implemented as an inorganic material-based light emitting diode. As another example, the display device 100 according to implementations of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed to extend in the first direction. Each of the plurality of gate lines GL may be disposed to extend in the second direction. Here, the first direction may be a column direction and the second direction may be a row direction. The first direction may be the row direction, and the second direction may be the column direction. For convenience of description, described below is an example in which each of the plurality of data lines DL is disposed in the column direction, and each of the plurality of gate lines GL is disposed in the row direction.

The data driving circuit 120 is a circuit for driving the plurality of data lines DL, and may out data signals to the plurality of data lines DL.

The data driving circuit 120 may receive digital image data DATA from the display controller 140 and may convert the received image data DATA into analog data signals and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The data driving circuit 120 may be connected to one side (e.g., an upper or lower side) of the display panel 110. In contrast, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but alternatively, the data driving circuit 120 may be disposed in the display area DA of the display panel 110.

The gate driving circuit 130 is a circuit for driving the plurality of gate lines GL, and may output gate signals to the plurality of gate lines GL.

The gate driving circuit 130 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to implementations of the disclosure, the gate driving circuit 130 may be embedded, in a gate in panel (GIP) type, in the display panel 110. When the gate driving circuit 130 is of the gate in panel type, the gate driving circuit 130 may be formed on the substrate 111 of the display panel 110 during the manufacturing process of the display panel 110.

In the display device 100 according to implementations of the disclosure, the gate driving circuit 130 may be disposed in the display area DA of the display panel 110. For example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA).

In the disclosure, the gate driving circuit 130 embedded in the display panel 110 in a gate-in-panel type may also be referred to as a “gate-in-panel circuit.”

The display controller 140 is a device for controlling the data driving circuit 120 and the gate driving circuit 130 and may control driving timings for the plurality of data lines DL and driving timings for the plurality of gate lines GL.

The display controller 140 may supply a data driving control signal DCS to the data driving circuit 120 to control the data driving circuit 120 and may supply a gate driving control signal GCS to the gate driving circuit 130 to control the gate driving circuit 130.

The display controller 140 may receive input image data from the host system 150 and supply image data DATA to the data driving circuit 120 based on the input image data.

The display controller 140 may be implemented as a separate component from the data driving circuit 120, or the display controller 140 and the data driving circuit 120 may be integrated into an integrated circuit (IC).

The display controller 140 may be a timing controller used in typical display technology, a control device that may perform other control functions as well as the functions of the timing controller, or a control device other than the timing controller, or may be a circuit in the control device. The display controller 140 may be implemented as various circuits or electronic components, such as an integrated circuit (IC), a field programmable gate array (FPGA), an application specific integrated circuit (ASIC), or a processor.

The display controller 140 may be mounted on a printed circuit board or a flexible printed circuit and may be electrically connected with the data driving circuit 120 and the gate driving circuit 130 through the printed circuit board or the flexible printed circuit.

The display controller 140 may transmit/receive signals to/from the data driving circuit 120 according to one or more predetermined interfaces. The interface may include, e.g., a low voltage differential signaling (LVDS) interface, an embedded clock point-point interface (EPI) interface, and a serial peripheral interface (SPI).

To provide a touch sensing function as well as an image display function, the display device 100 according to implementations of the disclosure may include a touch sensor and a touch sensing circuit that senses the touch sensor to detect whether a touch occurs by a touch object, such as a finger or pen, or the position of the touch.

The touch sensing circuit may include a touch driving circuit that drives and senses the touch sensor and generates and outputs touch sensing data and a touch controller that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit.

The touch sensor may be present in a touch panel form outside the display panel 110 or may be present inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate, together with signal lines and electrodes related to display driving, during the manufacturing process of the display panel 110.

The touch driving circuit may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or as a single device. The touch driving circuit and the data driving circuit may be implemented as separate devices or as a single device.

The display device 100 may further include a power supply circuit for supplying various types of power to the display driver integrated circuit and/or the touch sensing circuit.

The display device 100 according to implementations of the disclosure may be a mobile terminal, such as a smart phone or a tablet, or a monitor or television (TV) in various sizes but, without limited thereto, may be a display in various types and various sizes capable of displaying information or images.

The display device 100 according to implementations of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays.

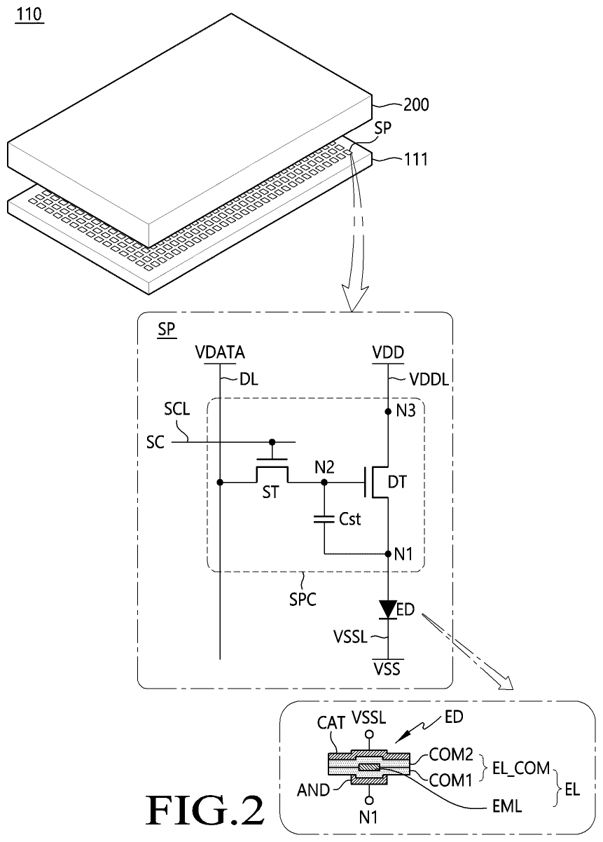

FIG. 2 is a view illustrating a display panel 110 according to an implementation of the disclosure.

Referring to FIG. 2, the display panel 110 may include a substrate 111 disposed in a plurality of subpixels SP and an encapsulation layer 200 on the substrate 111. Here, the encapsulation layer 200 may also be referred to as an encapsulation substrate or an encapsulation portion.

Referring to FIG. 2, when the display device 100 according to implementations of the disclosure is a self-luminous display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of pixel driving transistors and at least one capacitor for driving the light emitting element ED. In the disclosure, the subpixel circuit SPC may drive the light emitting element ED by supplying a driving current to the light emitting element ED at a predetermined timing. The light emitting element ED may be driven by a driving current to emit light.

The plurality of pixel driving transistors may include a driving transistor DT for driving the light emitting element ED and a scan transistor ST that is turned on or off according to the scan signal SC.

The driving transistor DT may supply a driving current to the light emitting element ED.

The scan transistor ST may be configured to control the electrical state of a corresponding node in the subpixel circuit SPC or to control the state or operation of the driving transistor DT.

The at least one capacitor may include a storage capacitor Cst for maintaining a constant voltage during a frame.

To drive the subpixel SP, a data signal VDATA as an image signal and a scan signal SC as a gate signal may be applied to the subpixel SP. Further, for driving the subpixel SP, a common pixel driving voltage including the driving voltage VDD and the base voltage VSS may be applied to the subpixel SP.

The light emitting element ED may include an anode AND, a light emitting element intermediate layer EL, and a cathode CAT. The light emitting element intermediate layer EL may be disposed between the anode AND and the cathode CAT.

When the light emitting element ED is an organic light emitting element, the light emitting element intermediate layer EL may include a light emitting layer EML, a first common intermediate layer COM1 between the anode AND and the light emitting layer EML, and a second common intermediate layer COM2 between the light emitting layer EML and the cathode. The light emitting layer EML may be disposed for each subpixel SP. In contrast, the first common intermediate layer COM1 and the second common intermediate layer COM2 may be commonly disposed over a plurality of subpixels SP. The light emitting layer EML may be disposed for each light emitting area, and the first common intermediate layer COM1 and the second common intermediate layer COM2 may be commonly disposed over the plurality of light emitting areas and the non-light emitting area. The first common intermediate layer COM1 and the second common intermediate layer COM2 may be collectively referred to as a common intermediate layer EL_COM.

For example, the first common intermediate layer COM1 may include a hole injection layer HIL and a hole transport layer HTL. The second common intermediate layer COM2 may include an electron transport layer ETL and an electron injection layer EIL. The hole injection layer may inject holes from the anode AND to the hole transport layer, the hole transport layer may transport the holes to the light emitting layer EML, the electron injection layer may inject electrons from the cathode CAT to the electron transport layer, and the electron transport layer may transport electrons to the light emitting layer EML.

For example, the cathode CAT may be electrically connected to the base voltage line VSSL. The base voltage VSS, which is one type of the common pixel driving voltage, may be applied to the cathode CAT through the base voltage line VSSL. The anode AND may be electrically connected to the first node N1 of the driving transistor DT of each subpixel SP. In the disclosure, “the base voltage VSS” may also be referred to as a “base voltage VSS”, and “the base voltage line VSSL” may also be referred to as a “base voltage line VSSL”.

For example, the anode AND may be a pixel electrode disposed in each subpixel SP, and the cathode CAT may be a common electrode commonly disposed in a plurality of subpixels SP. As another example, the cathode CAT may be a pixel electrode disposed in each subpixel SP, and the anode AND may be a common electrode commonly disposed in a plurality of subpixels SP. Hereinafter, for convenience of description, it is assumed that the anode AND is a pixel electrode and the cathode CAT is a common electrode.

Each light emitting element ED may include portions in which the anode AND, the light emitting element intermediate layer EL, and the cathode CAT overlap each other. A predetermined light emitting area may be formed by each light emitting element ED. For example, the emission area of each light emitting element ED may include an area in which the anode AND, the light emitting element intermediate layer EL, and the cathode CAT overlap.

For example, the light emitting element ED may be an organic light emitting diode (OLED), an inorganic light emitting diode (LED), or a quantum dot light emitting element. For example, when the light emitting element ED is an organic light emitting diode (OLED), the light emitting element intermediate layer EL of the light emitting element ED may include a light emitting element intermediate layer EL including an organic material.

The driving transistor DT may be a driving transistor for supplying a driving current to the light emitting element ED. The driving transistor DT may be connected between a driving voltage line VDDL and the light emitting element ED.

The driving transistor DT may include a first node N1 electrically connected to the light emitting element ED, a second node N2 to which the data signal VDATA may be applied, and a third node N3 to which the driving voltage VDD is applied from the driving voltage line DVL.

In the driving transistor DT, the second node N2 may be a gate node, the first node N1 may be a source node or a drain node, and the third node N3 may be a drain node or a source node. Hereinafter, for convenience of description, in the driving transistor DT, the second node N2 may be a gate node, the first node N1 may be a source node, and the third node N3 may be a drain node.

The scan transistor ST included in the subpixel circuit SPC illustrated in FIG. 2 may be a switching transistor for transferring the data signal VDATA, which is an image signal, to the second node N2, which is the gate node of the driving transistor DT.

The scan transistor ST may be controlled to be turned on and off by the scan signal SC, which is a gate signal applied through the scan line SCL, which is a type of the gate line GL, to control electrical connection between the second node N2 of the driving transistor DT and the data line DL. The drain electrode or the source electrode of the scan transistor ST may be electrically connected to the data line DL, the source electrode or the drain electrode of the scan transistor ST may be electrically connected to the second node N2 of the driving transistor DT, and the gate electrode of the scan transistor ST may be electrically connected to the scan line SCL.

The storage capacitor Cst may be electrically connected between the first node N1 and the first node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst may be an external capacitor intentionally designed to be outside the driving transistor DT, but not a parasite capacitor (e.g., Cgs or Cgd) which is an internal capacitor that may be present between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

When the display panel 110 has a top emission structure, at least a portion of the subpixel circuit SPC may overlap at least a portion of the light emitting element ED in a vertical direction. In contrast, when the display panel 110 has a bottom emission structure, the subpixel circuit SPC may not overlap the light emitting element ED in the vertical direction.

As illustrated in FIG. 2, the subpixel circuit SPC may have a 2T (Transistor)1C (Capacitor) structure including two transistors DT and ST and one capacitor Cst. In some cases, the subpixel circuit SPC may further include one or more transistors or may further include one or more capacitors.

For example, the subpixel circuit SPC may have a 8T1C structure including 8 transistors and 1 capacitor. As another example, the subpixel circuit SPC may have a 6T2C structure including 6 transistors and 2 capacitors. As another example, the subpixel circuit SPC may have a 7T1C structure including 7 transistors and 1 capacitor.

Depending on the structure of the subpixel circuit SPC, the type and number of gate lines or the gate signals supplied to the subpixel SP may vary.

Further, the type and the number of common pixel driving voltages supplied to the subpixel SP may vary according to the structure of the subpixel circuit SPC.

Since the circuit elements (especially the light emitting element ED implemented as an organic light emitting diode (OLED) including an organic material) in each subpixel SP are vulnerable to external moisture or oxygen, the encapsulation layer 200 for preventing external moisture or oxygen from penetrating into the circuit elements (especially the light emitting element ED) may be disposed on the display panel 110. The encapsulation layer 200 may be configured in various forms so that the light emitting elements ED do not contact moisture or oxygen.

Referring to FIG. 2, the display device 100 according to implementations of the disclosure may further include a touch sensor layer TSL including a plurality of sensor electrodes and a touch sensing circuit TSL configured to sense the plurality of sensor electrodes to determine the presence or absence of a touch or the coordinates of a touch.

The touch sensor layer TSL may be embedded in the display panel 110. For example, the touch sensor layer TSL may be disposed on the encapsulation layer 200 in the display panel 110.

The display panel 110 may include not only the touch sensor layer TSL, but also a plurality of touch pads where the touch sensing circuit TSL is electrically connected, and a plurality of touch routing wires TL for electrically connecting the plurality of sensor electrodes included in the touch sensor layer TSL and the plurality of touch pads where the touch sensing circuit TSL is connected.

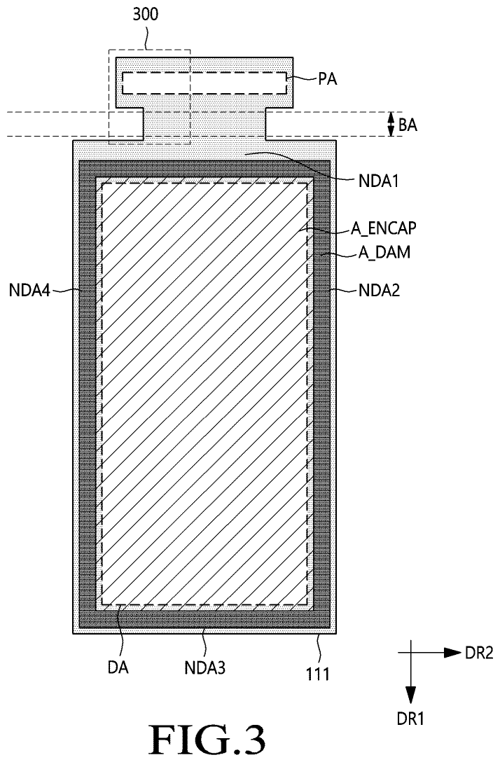

FIG. 3 illustrates a substrate 111 of a display panel 110 according to implementations of the disclosure.

Referring to FIG. 3, the substrate 111 of the display panel 110 according to implementations of the disclosure may include a display area DA in which an image may be displayed and a non-display area NDA in which an image is not displayed.

Referring to FIG. 3, the non-display area NDA may include a first non-display area NDA1 positioned in the first direction from the display area DA, a second non-display area NDA2 positioned in the second direction from the display area DA, a third non-display area NDA3 positioned in a direction opposite to the first direction from the display area DA, and a fourth non-display area NDA4 positioned in a direction opposite to the second direction from the display area DA. For example, the first direction may be a column direction (Y-axis direction), and the second direction crossing the first direction may be a row direction (X-axis direction).

Referring to FIG. 3, the first non-display area NDA1 may include a pad area PA in which a plurality of pads are disposed.

In the pad area PA, a plurality of pads where the driving circuit is electrically connected may be disposed. A plurality of driving circuits or printed circuit boards may be electrically connected. For example, the plurality of pads may include a plurality of display pads and a plurality of touch pads. A plurality of data lines DL, a driving voltage line VDDL and a base voltage line VSSL may be electrically connected to the plurality of pads illustrated in FIG. 3. A plurality of touch routing lines TL may be electrically connected to the plurality of touch pads.

Referring to FIG. 3, the first non-display area NDA1 may further include a bending area BA. In this case, the substrate 111 may be a flexible substrate. In some cases, the first non-display area NDA1 may not include the bending area BA.

Referring to FIG. 3, the display panel 110 may further include a ground line disposed in the non-display area NDA of the substrate 111. The ground line may be disposed from one point of the pad area PA to another point of the pad area PA via the second non-display area NDA2, the third non-display area NDA3, and the fourth non-display area NDA4.

Referring to FIG. 3, the display panel 110 may include an encapsulation layer area A_ENCAP and a dam area A_DAM.

Referring to FIG. 3, the encapsulation layer area A_ENCAP may be an area where the encapsulation layer 200 is disposed. In the display panel 110 according to implementations of the disclosure, the encapsulation layer 200 may have a structure in which an inorganic film and an organic film are stacked. In this case, an edge of the encapsulation layer 200 may be regarded as an edge of the organic film.

Referring to FIG. 3, the dam area A_DAM may be an area surrounding the encapsulation layer area A_ENCAP. A structure functioning as a dam may be positioned in the dam area A_DAM. The dam may prevent the liquid organic film from flowing out.

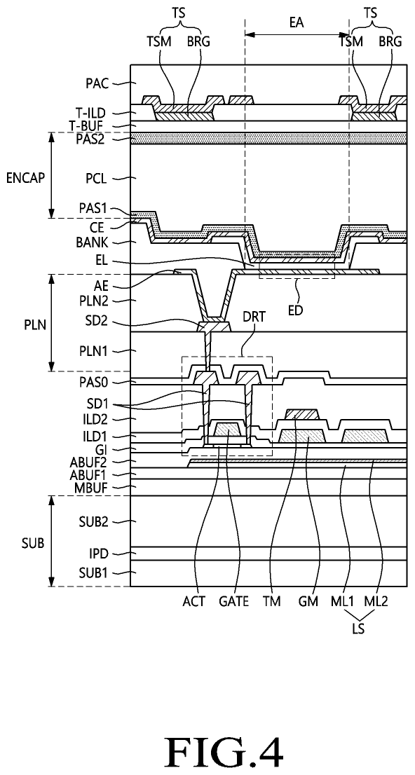

FIG. 4 is a cross-sectional view illustrating a portion of a display area DA of a display panel 110 according to implementations of the disclosure.

Referring to FIG. 4, the substrate SUB may include a first substrate SUB1, an interlayer insulation film IPD, and a second substrate SUB2. The interlayer insulation film IPD may be positioned between the first substrate SUB1 and the second substrate SUB2. By configuring the substrate SUB with the first substrate SUB1, the interlayer insulation film IPD and the second substrate SUB2, it is possible to prevent moisture penetration. For example, the first substrate SUB1 and the second substrate SUB2 may be polyimide (PI) substrates. The first substrate SUB1 may be referred to as a primary PI substrate, and the second substrate SUB2 may be referred to as a secondary PI substrate.

Referring to FIG. 4, on the substrate SUB, various patterns ACT, SD1, and GATE1 for forming a transistor, such as a driving transistor DRT, various insulation films MBUF, ABUF1, ABUF2, GI, ILD1, ILD2, and PAS0, and various metal patterns TM, GM, ML1, and ML2 may be disposed.

Referring to FIG. 4, a multi-buffer layer MBUF may be disposed on the second substrate SUB2. A first active buffer layer ABUF1 may be disposed on the multi-buffer layer MBUF.

A first metal layer ML1 and a second metal layer ML2 may be disposed on the first active buffer layer ABUF1. The first metal layer ML1 and the second metal layer ML2 may be a light shield layer LS for shielding light.

A second active buffer layer ABUF2 may be disposed on the first metal layer ML1 and the second metal layer ML2. An active layer ACT of the driving transistor DRT may be disposed on the second active buffer layer ABUF2.

A gate insulation film GI may be disposed while covering the active layer ACT.

A first gate electrode GATE1 of the driving transistor DRT may be disposed on the gate insulation film GI. In this case, at a position different from the position where the driving transistor DRT is formed, a gate material layer GM, together with the first gate electrode GATE1 of the driving transistor DRT, may be disposed on the gate insulation film GI.

The first interlayer insulation film ILD1 may be disposed while covering the first gate electrode GATE1 and the gate material layer GM. A metal pattern TM may be disposed on the first inter-layer insulation film ILD1. The metal pattern TM may be located in a position different from the position where the driving transistor DRT is formed. The second inter-layer insulation film ILD2 may be disposed while covering the metal pattern TM on the first inter-layer insulation film ILD1.

Two first source-drain electrode patterns SD1 may be disposed on the second interlayer insulation film ILD2. One of the two first source-drain electrode patterns SD1 is the source node of the driving transistor DRT, and the other is the drain node of the driving transistor DRT. The two first source-drain electrode patterns SD1 may be electrically connected with the two opposite sides of the active layer ACT through the contact hole of the second inter-layer insulation film ILD2, the first inter-layer insulation film ILD1, and the gate insulation film GI.

A portion of the active layer ACT overlapping the first gate electrode GATE1 is a channel area. One of the two first source-drain electrode patterns SD1 may be connected to one side of the channel area in the active layer ACT, and the other one of the two first source-drain electrode patterns SD1 may be connected to the other side of the channel area in the active layer ACT.

A passivation layer PAS0 is disposed while covering the two first source-drain electrode patterns SD1. A planarization layer PLN may be disposed on the passivation layer PAS0. The planarization layer PLN may include a first planarization layer PLN1 and a second planarization layer PLN2.

The first planarization layer PLN1 may be disposed on the passivation layer PAS0.

A second source-drain electrode pattern SD2 may be disposed on the first planarization layer PLN1. The second source-drain electrode pattern SD2 may be connected with one of the two first source-drain electrode patterns SD1 (corresponding to the second node N2 of the driving transistor DRT in the subpixel SP of FIG. 3) through the contact hole of the first planarization layer PLN1.

The second planarization layer PLN2 may be disposed while covering the second source-drain electrode pattern SD2. A light emitting element ED may be disposed on the second planarization layer PLN2.

In the stacked structure of the light emitting element ED, the anode electrode AE may be disposed on the second planarization layer PLN2. The anode electrode AE may be electrically connected to the second source-drain electrode pattern SD2 through the contact hole of the second planarization layer PLN2.

The bank BANK may be disposed while covering a portion of the anode electrode AE. A portion of the bank BANK corresponding to the light emitting area EA of the subpixel SP may be opened.

A portion of the anode electrode AE may be exposed through an opening (open portion) of the bank BANK. A light emitting layer EL may be positioned on a side surface of the bank BANK and the opening (open portion) of the bank BANK. The whole or part of the light emitting layer EL may be positioned between adjacent banks BANK.

In the opening of the bank BANK, the light emitting layer EL may contact the anode electrode AE. A cathode electrode CE may be disposed on the light emitting layer EL.

The light emitting element ED may be formed by the anode electrode AE, the light emitting layer EL, and the cathode electrode CE. The light emitting layer EL may include an organic film.

An encapsulation layer ENCAP may be disposed on the above-described light emitting element ED.

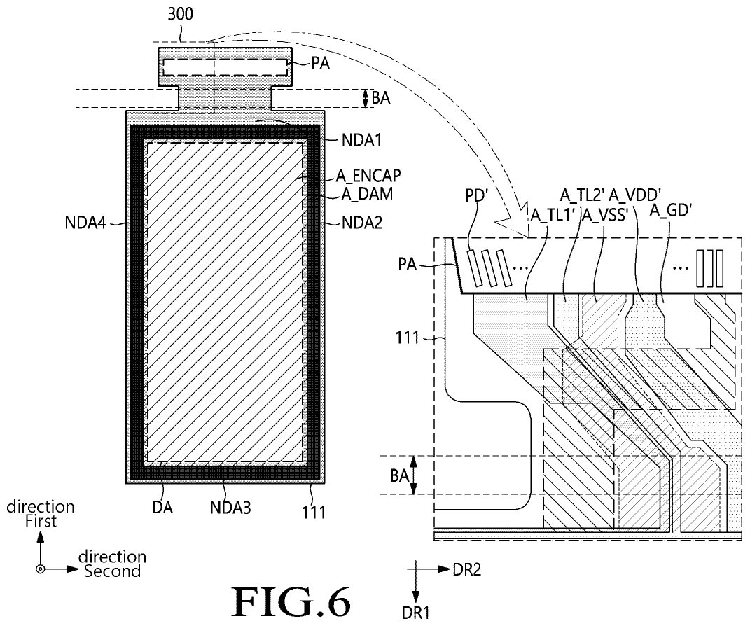

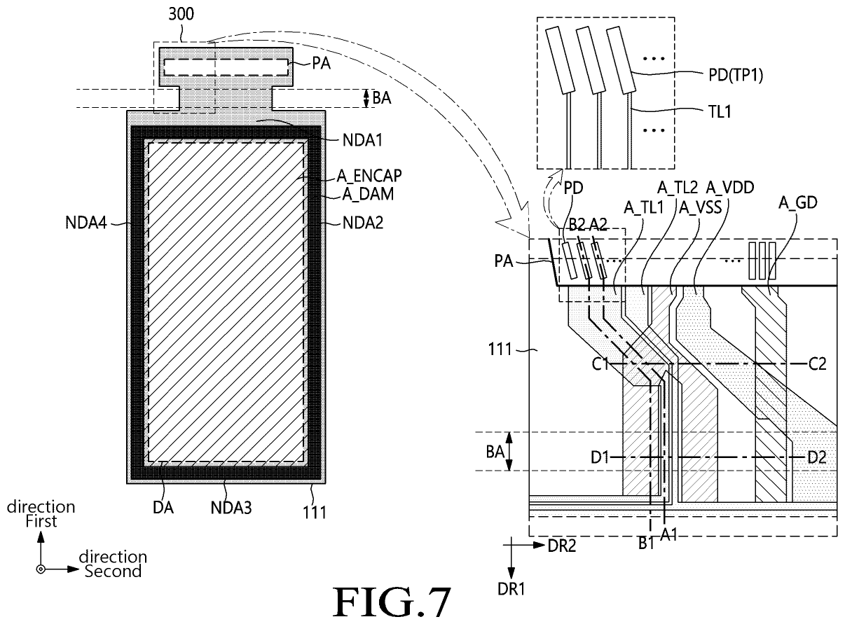

The encapsulation layer ENCAP may have a single-layer structure or a multi-layer structure. For example, as illustrated in FIG. 6 and FIG. 7, the encapsulation layer ENCAP may include a first inorganic encapsulation layer PAS1, an organic encapsulation layer PCL, and a second inorganic encapsulation layer PAS2.

For example, the first inorganic encapsulation layer PAS1 and the second inorganic encapsulation layer PAS2 may be inorganic films, and the organic encapsulation layer PCL may be an organic film. Among the first inorganic encapsulation layer PAS1, the organic encapsulation layer PCL, and the second encapsulation layer PAS2, the organic encapsulation layer PCL may be the thickest and serve as a planarization layer.

The first inorganic encapsulation layer PAS1 may be disposed on the cathode electrode CE and be disposed closest to the light emitting element ED. The first inorganic encapsulation layer PAS1 may be formed of an inorganic insulating material capable of low-temperature deposition. For example, the first inorganic encapsulation layer PAS1 may be formed of silicon nitride (SiNx), silicon oxide (SiOx), silicon oxynitride (SiON), or aluminum oxide (Al2O3). Since the first inorganic encapsulation layer PAS1 is deposited in a low temperature atmosphere, the first inorganic encapsulation layer PAS1 may prevent damage to the light emitting layer EL including an organic material vulnerable to a high temperature atmosphere during the deposition process.

The organic encapsulation layer PCL may be formed in a smaller area than the first inorganic encapsulation layer PAS1. In this case, the organic encapsulation layer PCL may be formed to expose two opposite ends of the first inorganic encapsulation layer PAS1. The organic encapsulation layer PCL serves as a buffer for relieving stress between layers due to bending of the display device 100 and may also serve to enhance planarization performance. For example, the organic encapsulation layer PCL may be an acrylic resin, an epoxy resin, polyimide, polyethylene, or silicon oxycarbon (SiOC) and be formed of an organic insulating material. For example, the organic encapsulation layer PCL may be formed through an inkjet scheme.

The second inorganic encapsulation layer PAS2 may be formed over the substrate SUB, where the organic encapsulation layer PCL is formed, to cover the upper surface and side surfaces of each of the organic encapsulation layer PCL and the first inorganic encapsulation layer PAS1. The second inorganic encapsulation layer PAS2 may minimize or block penetration of external moisture or oxygen into the first inorganic encapsulation layer PAS1 and the organic encapsulation layer PCL. For example, the second encapsulation layer PAS2 is formed of an inorganic insulating material, such as silicon nitride (SiNx), silicon oxide (SiOx), silicon oxynitride (SiON), or aluminum oxide (Al2O3).

Referring to FIG. 4, when the touch sensor TS is of a type embedded in the display panel PNL, the touch sensor TS may be disposed on the encapsulation layer ENCAP. The touch sensor structure is described below in detail.

A touch buffer film T-BUF may be disposed on the encapsulation layer ENCAP. A touch sensor TS may be disposed on the touch buffer film T-BUF.

The touch sensor TS may include touch sensor metals TSM and a bridge metal BRG positioned on different layers.

A touch interlayer insulation film T-ILD may be disposed between the touch sensor metals TSM and the bridge metal BRG.

For example, the touch sensor metals TSM may include a first touch sensor metal TSM, a second touch sensor metal TSM, and a third touch sensor metal TSM that are disposed adjacent to each other. The third touch sensor metal TSM is disposed between the first touch sensor metal TSM and the second touch sensor metal TSM and, when the first touch sensor metal TSM and the second touch sensor metal TSM are electrically connected to each other, the first touch sensor metal TSM and the second touch sensor metal TSM may be electrically connected to each other through the bridge metal BRG positioned on a different layer. The bridge metal BRG may be insulated from the third touch sensor metal TSM by the touch interlayer insulation film T-ILD.

When the touch sensor TS is formed on the display panel PNL, moisture may be generated from the chemical solution (e.g., developer or etchant) used in the process. By disposing the touch sensor TS on the touch buffer film T-BUF, it is possible to prevent a chemical solution or moisture from penetrating into the light emitting layer EL including an organic material during the manufacturing process of the touch sensor TS. Thus, the touch buffer film T-BUF may prevent damage to the light emitting layer EL vulnerable to chemicals or moisture.

The touch buffer film T-BUF is formed of an organic insulation material with a low permittivity of 1 to 3 and formed at a low temperature which is not more than a predetermined temperature (e.g., 100° C.) to prevent damage to the light emitting layer EL containing the organic material vulnerable to high temperature. For example, the touch buffer film T-BUF may be formed of an acrylic-based, epoxy-based, or siloxane-based material. As the display device 100 is bent, the encapsulation layer ENCAP may be damaged, and the touch sensor metal positioned on the touch buffer layer T-BUF may be broken. Even when the display device 100 is bent, the touch buffer layer T-BUF formed of an organic insulating material and having planarization capability may prevent damage to the encapsulation layer ENCAP and/or breakage of the metals TSM and BRG constituting the touch sensor TS.

A protection layer PAC may be disposed while covering the touch sensor TS. The protective layer PAC may be an organic insulation film.

The display device according to an implementation may perform touch sensing in the mutual capacitance-based touch sensing scheme or the self-capacitance-based touch sensing scheme. In the following example, the display device performs mutual-capacitance-based touch sensing and has a touch sensor structure for the same, for ease of description.

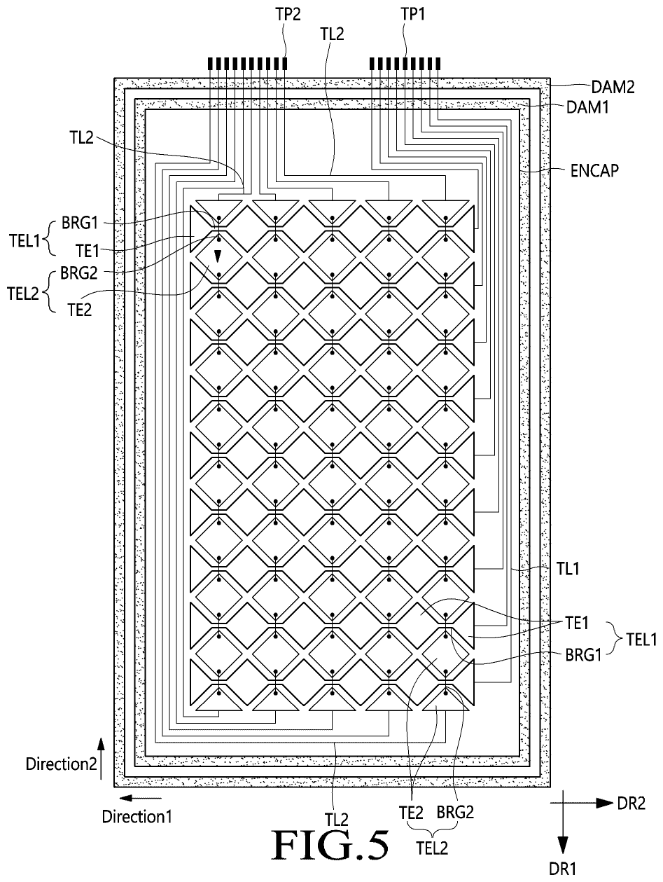

FIG. 5 is a view illustrating components for touch sensing according to implementations of the disclosure.

Referring to FIG. 5, a touch sensor structure for mutual-capacitance-based touch sensing may include a plurality of first touch electrode lines TEL1 and a plurality of second touch electrode lines TEL2. Here, the plurality of first touch electrode lines X-TEL and the plurality of second touch electrode lines Y-TEL may be positioned on the encapsulation layer ENCAP.

Each of the plurality of first touch electrode lines TEL1 may be disposed in a first direction Direction1, and each of the plurality of second touch electrode lines TEL2 may be disposed in a second direction Direction2. The first direction Direction1 and the second direction Direction2 are directions that cross each other.

Referring to FIG. 5, each of the plurality of first touch electrode lines TEL1 may be composed of a plurality of first touch electrodes TE1 that are electrically connected. Each of the second touch electrode lines TEL2 may be constituted of a plurality of second touch electrodes Y-TE electrically connected with each other. The plurality of first touch electrodes TE1 and the plurality of second touch electrodes TE2 are included in the plurality of touch electrodes TE. The plurality of first touch electrodes TE1 constituting each of the plurality of first touch electrode lines TEL1 may be driving touch electrodes, and the plurality of second touch electrodes TE2 constituting each of the plurality of second touch electrode lines TEL2 may be sensing touch electrodes. In this case, each of the plurality of first touch electrode lines TEL1 corresponds to the driving touch electrode line, and each of the plurality of second touch electrode lines TEL2 corresponds to the sensing touch electrode line.

Referring to FIG. 5, a touch sensor metal for touch sensing may include a plurality of touch routing lines TL as well as the plurality of first touch electrode lines TEL1 and the plurality of second touch electrode lines TEL2. The plurality of touch routing line TL may include one or more first touch routing line TL1 connected to each of the plurality of first touch electrode lines TEL1, and one or more second touch routing line TL2 connected to each of the plurality of second touch electrode lines TEL2.

Referring to FIG. 5, each of the plurality of first touch electrode lines TEL1 may include a plurality of first touch electrodes TE1 disposed in the same row or column, and one or more first bridge metals BRG1 electrically connecting them. Here, the first bridge metal BRG1 connecting the two adjacent first touch electrodes TE1 may be a metal integrated with the two adjacent first touch electrodes TE1 or may also be a metal connected to the two adjacent first touch electrodes TE1 through a contact hole.

Each of the plurality of second touch electrode lines TEL2 may include a plurality of second touch electrodes TE2 disposed in the same column or row, and one or more second bridge metals BRG2 electrically connecting them. Here, the second bridge metal BRG2 connecting the two adjacent second touch electrodes TE2 may be a metal integrated with the two adjacent second touch electrodes TE2 or may also be a metal connected to the two adjacent second touch electrodes TE2 through a contact hole.

Here, the first bridge metal BRG1 or the second bridge metal BRG2 connected to the first touch electrode TE1 or the second touch electrode TE2 through the contact hole may be referred to as a “connection pattern”.

In an area (a touch electrode line crossing area) where the first touch electrode line TEL1 and the second touch electrode line TEL2 cross each other, the first bridge metal BRG1 and the second bridge metal BRG2 may cross each other.

As described above, when the first bridge metal BRG1 and the second bridge metal BRG2 cross each other in the touch electrode line crossing area, the first bridge metal BRG1 and the second bridge metal BRG2 may be disposed in different layers.

Therefore, in order to cross the plurality of first touch electrode lines TEL1 and the plurality of second touch electrode lines TEL2, the plurality of first touch electrodes TE1, the plurality of first bridge metals BRG2, the plurality of second touch electrode lines TEL2, and the plurality of second bridge metals BRG2 may be disposed in two or more layers.

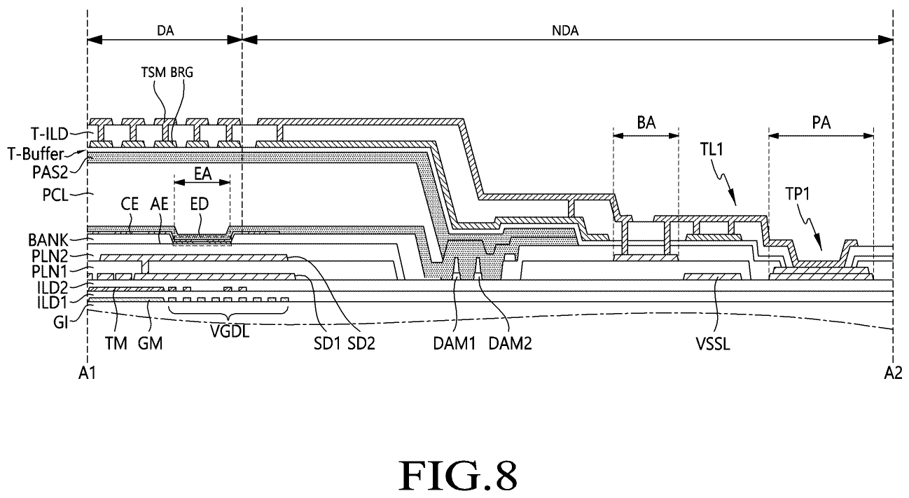

Referring to FIG. 8, each of the plurality of first touch electrode lines TEL1 is electrically connected to the corresponding first touch pad TP1 through one or more first touch routing lines TL1. In other words, the first touch electrode TE1 disposed on the outermost side among the plurality of first touch electrodes TE1 included in the one first touch electrode line TEL1 is electrically connected to the corresponding first touch pad TP1 through the first touch routing line TL1.

Each of the plurality of second touch electrode lines TEL2 is electrically connected to the corresponding second touch pad TP2 through one or more second touch routing lines TL2. In other words, the second touch electrode TE2 disposed on the outermost side among the plurality of second touch electrodes TE2 included in one second touch electrode line TEL2 is electrically connected to the corresponding second touch pad TP2 through the second touch routing line TL2. Hereinafter, wires or lines electrically connected to the touch pads TP1 and TP2 are described in more detail.

FIG. 6 is a view illustrating a non-display area NDA of a display panel 110 according to implementations of the disclosure.

The substrate 111 illustrated in FIG. 6 is the same as the substrate 111 illustrated in FIG. 3. Therefore, the repeated description is omitted. Referring to FIG. 6, an area 300 where a portion of the non-display area NDA is enlarged may be identified.

Referring to FIG. 6, the plurality of pads PD′ may be disposed in the pad area PA.

The lines disposed in the first touch routing line area A_TL1′ may be electrically connected to a portion of the plurality of pads PD′. The plurality of first touch routing lines may be disposed in the first touch routing line area A_TL1′.

The lines disposed in the second touch routing line area A_TL2′ may be electrically connected to a portion of the plurality of pads PD′. The plurality of second touch routing lines may be disposed in the second touch routing line area A_TL2′.

The lines disposed in the base voltage line area A_VSS′ may be electrically connected to a portion of the plurality of pads PD′. A plate for supplying a base voltage may be disposed in the base voltage line area A_VSS′.

The lines disposed in the driving voltage line VDDL area A_VDD′ may be electrically connected to a portion of the plurality of pads PD′. A plate for supplying a driving voltage may be disposed in the area A_VDD′ of the driving voltage line VDDL.

The lines disposed in the gate driving voltage line area A_GD′ may be electrically connected to a portion of the plurality of pads PD′. The plurality of gate driving voltage lines VGDL may be disposed in the gate driving voltage line area A_GD′.

Referring to FIG. 6, when viewed in FIG. 6, the first touch routing line area A_TL1′ may be positioned on the leftmost side. The first touch routing line area A_TL1′ may be electrically connected to a portion of the plurality of pads PD′, and the first touch routing line area A_TL1′ may extend in the first direction DR1. When the first touch routing line area A_TL1′ extends in the first direction DR1, the first touch routing line area A_TL1′ may be inclined toward the right. For example, the first touch routing line area A_TL1′ may be obliquely disposed toward a lower right direction. Thereafter, the first touch routing line area A_TL1′ may extend in the first direction DR1 past the bending area BA, and the first touch routing line area A_TL1′ may be disposed to bend to the left.

The second touch routing line area A_TL2′ may be positioned on the right side of the first touch routing line area A_TL1′. The second touch routing line area A_TL2′ may be electrically connected to a portion of the plurality of pads PD′, and the second touch routing line area A_TL2′ may extend in the first direction DR1. When the second touch routing line area A_TL2′ extends in the first direction DR1, the second touch routing line area A_TL2′ may be inclined toward the right. For example, the second touch routing line area A_TL2′ may be obliquely disposed toward a lower right direction. Thereafter, the second touch routing line area A_TL2′ may extend in the first direction DR1 past the bending area BA, and the second touch routing line area A_TL2′ may extend to the left and right.

The base voltage line area A_VSS′ may be electrically connected to a portion of the plurality of pads PD′, and the base voltage line area A_VSS′ may extend in the first direction DR1. The base voltage line area A_VSS′ may extend in the first direction DR1 while being positioned on the right side of the second touch routing line area A_TL2′. When the base voltage line area A_VSS′ extends in the first direction DR1, the base voltage line area A_VSS′ may overlap the first touch routing line area A_TL1′ and the second touch routing line area A_TL2′. When the base voltage line area A_VSS′ overlaps the first touch routing line area A_TL1′ and the second touch routing line area A_TL2′, the base voltage line area A_VSS′ may also overlap the gate driving voltage line area A_GD′. The base voltage line area A_VSS′ may not overlap the driving voltage line VDDL area A_VDD′.

The driving voltage line VDDL area A_VDD′ may be positioned on the right side of the base voltage line area A_VSS′. The driving voltage line VDDL area A_VDD′ may be electrically connected to a portion of the plurality of pads PD′, and the driving voltage line VDDL area A_VDD′ may extend in the first direction DR1. When the driving voltage line VDDL area A_VDD′ extends in the first direction DR1, the driving voltage line A_VDD′ may be inclined toward the right.

The gate driving voltage line area A_GD′ may be electrically connected to a portion of the plurality of pads PD′, and the position may be a right area of the driving voltage line VDDL area A_VDD′. The gate driving voltage line area A_GD′ may extend in the first direction DR1 and then be bent to the left and extend, and then may extend again in the first direction DR1. In other words, the gate driving voltage line area A_GD′ may be bent twice at 90 degrees. In this case, the gate driving voltage line area A_GD′ may overlap the first touch routing line area A_TL1′ and the second touch routing line area A_TL2′. Further, the gate driving voltage line area A_GD′ may overlap the base voltage line area A_VSS′ and the driving voltage line VDD′ A_VDD′. The gate driving voltage line area A_GD′ may pass through the bending area BA while extending in the first direction DR1.

Meanwhile, referring to FIG. 6, the first touch routing line area A_TL1′ and the second touch routing line area A_TL2′ may overlap the base voltage line area A_VSS′ except for a portion electrically connected to the pad. Lines having a single line form or a dual line form may be disposed in the first touch routing line area A_TL1′ and the second touch routing line area A_TL2′. The single line form refers to a form in which one line is extended, and the dual line form refers to a form in which two lines are connected in parallel. When the first touch routing line area A_TL1′ and the second touch routing line area A_TL2′ overlap the base voltage line area A_VSS′, it may be difficult to design a dual line form due to lack of space. Further, even when designed in a single line form, additional design challenges may arise, such as increased resistance and heightened noise issues.

Accordingly, implementations of the disclosure may provide a display device capable of efficiently arranging lines by changing the arrangement of lines.

Implementations of the disclosure may provide a display device capable of efficiently arranging lines by minimizing an area where touch routing line areas and the base voltage line area A_VSS′ overlap.

Implementations of the disclosure may provide a display device capable of low-power driving by efficiently arranging lines. A detailed description thereof is given below.

FIG. 7 is a view illustrating a non-display area NDA of a display panel 110 according to implementations of the disclosure.

A plurality of first touch routing lines TL1 may be disposed in the first touch routing line area A_TL1. The first touch routing line TL1 may be electrically connected to the plurality of first touch pads PD1. The first touch routing line area A_TL1 may extend in the first direction DR1. The first touch routing line area A_TL1 may pass through the bending area BA. The first touch routing line area A_TL1 may be disposed to bend to the left after passing through the bending area BA.

The plurality of second touch routing lines may be disposed in the second touch routing line area A_TL2. The second touch routing line area A_TL2 may be disposed on the right side of the first touch routing line area A_TL1 to be adjacent to the first touch routing line area A_TL1. The second touch routing line area A_TL2 may be disposed to bend to the left and right after passing through the bending area BA.

A portion of the base voltage line VSSL area A_VSS adjacent to the pad area PA may be disposed on the right side of the second touch routing line area A_TL2 to be adjacent to the second touch routing line area A_TL2. The area A_VSS of the base voltage line VSSL may have a Y shape rotated by 180 degrees. In this case, the first touch routing line area A_TL1 and the second touch routing line area A_TL2 may be disposed in an area between the lower sides of the Y shape rotated by 180 degrees. In other words, the first touch routing line area A_TL1 and the second touch routing line area A_TL2 may be disposed between two lines into which the base voltage line VSSL area A_VSS is branched.

The area A_VSS of the base voltage line VSSL may be electrically connected to a single or multiple pads PD, and may extend in the first direction DR1. The base voltage line VSSL area A_VSS may have two or more plate shapes but, without limitations thereto, may have a plurality of line shapes.

A portion of the driving voltage line VDDL area A_VDD adjacent to the pad area PA may be disposed on the right side of the base voltage line VSSL area A_VSS to be adjacent to the base voltage line VSSL area A_VSS. The driving voltage line VDDL area A_VDD may extend in the first direction DR1 through the bending area BA.

A portion of the gate driving voltage line VGDL area A_GD adjacent to the pad area PA may be disposed on the right side of the driving voltage line VDDL area A_VDD to be adjacent to the driving voltage line area A_VDD. The gate driving voltage line VGDL area A_GD may pass through the bending area BA and extend in the first direction DR1. The gate driving voltage line VGDL may extend from the pad area PA to the bending area BA. The gate driving voltage line VGDL area A_GD may overlap the driving voltage line VDDL area A_VDD.

A partial plan view illustrating the non-display area NDA of the display panel 110 has been described with reference to FIG. 7, and a cross-sectional view thereof is described below. Referring to FIG. 7, areas A1-A2, B1-B2, C1-C2, and D1-D2 may be identified. Hereinafter, it is described in more detail.

FIG. 8 is a cross-sectional view of area A1-A2 of FIG. 7□.

The cross-sectional structure illustrated in FIG. 8 is the same as the cross-sectional structure illustrated in FIG. 4. Therefore, repeated descriptions are omitted.

The gate material layer GM may be disposed on the gate insulation film GI. The first interlayer insulation film ILD1 may be disposed on the gate material layer GM. The metal pattern TM may be disposed on the first interlayer insulation film ILD1. A portion of the gate material layer GM may overlap the metal pattern TM. A portion of the gate material layer GM may be a gate driving voltage line VGDL. A portion of the gate driving voltage line VGDL may be electrically connected to the metal pattern TM, and in this case, may contact the same through the contact hole formed in the first interlayer insulation film ILD1.

The first source drain electrode pattern SD1 may be disposed on the second interlayer insulation film ILD2. The first planarization layer PLN1 may be disposed on the first source drain electrode pattern SD1. The second source drain electrode pattern SD2 may be disposed on the first planarization layer PLN1. The second planarization layer PLN2 may be disposed on the second source drain electrode pattern SD2.

Referring to FIG. 8, the first source drain electrode pattern SD1 is patterned. It is described from the leftmost portion of FIG. 8. A portion of the first source drain electrode pattern SD1 may overlap the gate material layer GM and the metal pattern TM. In this case, the first source drain electrode pattern SD1 may extend to the right portion. Accordingly, the first source drain electrode pattern SD1 may overlap the gate driving voltage line VGDL.

Referring to the rightmost side of FIG. 8, the pad area PA may be identified. A plurality of first touch pads may be disposed in the pad area PA. The plurality of first touch pads may include the respective materials of the first source drain electrode pattern SD1, the second source drain electrode pattern SD2, and the touch sensor metal TSM. In other words, the plurality of first touch pads may be in the form of multilayer metal. Referring to the pad area PA, the second source drain electrode pattern SD2 may overlap the first source drain electrode pattern SD1. The touch sensor metal TSM may overlap the second source drain electrode pattern SD2.

Referring to FIG. 8, a base voltage line VSSL may be disposed between the bending area BA and the pad area PA. In this case, the base voltage line VSSL may include the material of the first source drain electrode pattern SD1.

Two dams DAM1 and DAM2 may be disposed between the bending area BA and the display area DA. The dam may include two organic insulation layer materials, but may also include one organic insulation layer material. The second dam DAM2 may be disposed outside the first dam DAM1. A portion of a component including the bank BANK material may be disposed outside the second dam DAM2, which may function as a dam.

A light emitting element ED may be disposed on the side of the display area DA. After the bank BANK is entirely deposited, a portion of the bank BANK may be etched and removed to define a position where the light emitting element ED is to be disposed. The area where the bank BANK is etched out may correspond to the display area DA. The non-display area NDA may be an area outside the display area DA. A touch sensor metal TSM and a bridge metal BRG may be disposed in the display area DA, and they may constitute a touch sensor. A first touch routing line TL1 may be disposed in the non-display area NDA.

The first touch routing line TL1 may extend from the upper surface of the encapsulation layer PCL to the side surface of the encapsulation layer PCL. The first touch routing line TL1 may extend along an inclined surface formed on a side surface of the encapsulation layer PCL, and the first touch routing line TL1 may pass through the bending area BA. The first touch routing line TL1 may be in the dual line form composed of a touch sensor metal TSM and a bridge metal BRG, but may be in the single line form. The first touch routing line TL1 may pass through the bending area BA and extend to the pad area PA. The first touch routing line TL1 may be electrically connected to the first touch pad TP1. Each of the first touch routing line TL1 and the first touch pad TP1 may include the material of the touch sensor metal TSM, but may share the material of the continuous touch sensor metal TSM. The first touch routing line TL1 may contact the second source drain electrode pattern SD2 in the bending area BA. Accordingly, even when the first touch routing line TL1 is bent in the bending area BA, disconnection may be prevented.

Referring to FIG. 8, in the area A1-A2, the first touch routing line TL1 may overlap the base voltage line VSSL in a portion thereof. In other words, since a portion of the first touch routing line TL1 overlaps the base voltage line VSSL, the space where the first touch routing line TL1 is to be designed may be relatively increased. Accordingly, the first touch routing line TL1 may be easily designed as a dual line. Hereinafter, a cross-sectional view of area B1-B2 is described.

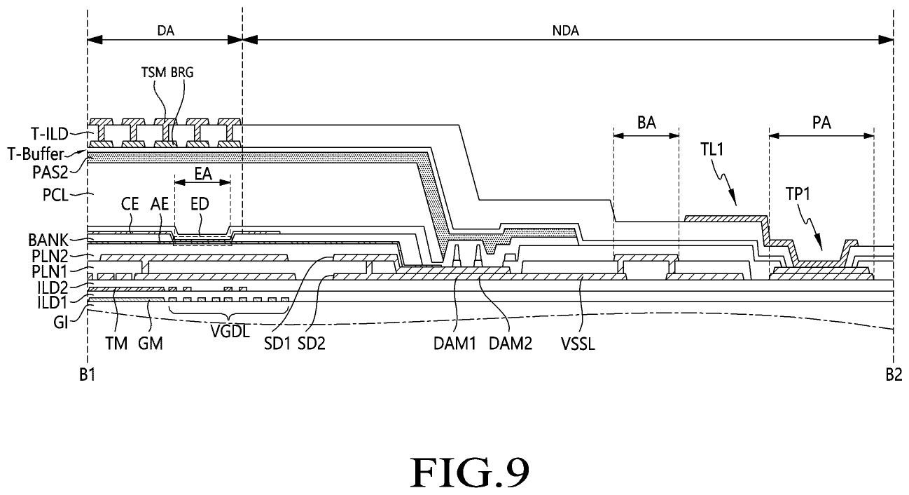

FIG. 9 is a cross-sectional view of area B1-B2 of FIG. 7.

The cross-sectional structure illustrated in FIG. 9 is the same as the cross-sectional structure illustrated in FIG. 4. Therefore, repeated descriptions are omitted. Further, a description of the portion of the cross-sectional structure illustrated in FIG. 9 that is the same as the cross-sectional structure illustrated in FIG. 8 is omitted.

Referring to FIG. 9, the base voltage line VSSL may include materials included in the first source drain electrode pattern SD1, the second source drain electrode pattern SD2, and the cathode electrode CE.

Referring to FIG. 9, the first touch routing line TL1 may extend from the pad area PA to the bending area BA. The first touch routing line TL1 may overlap the base voltage line VSSL in an area adjacent to the bending area BA. The base voltage line VSSL may pass through the bending area BA and extend to the display area DA. In the bending area BA, the base voltage line VSSL may include the material of the second source drain electrode pattern SD2. In the bending area BA, the second source drain electrode pattern SD2 may be electrically connected to the first source drain electrode pattern SD1 through the contact hole formed in the first planarization layer PLN1. Thereafter, the first source drain electrode pattern SD1 may extend from the bending area BA to the display area DA. The first source drain electrode pattern SD1 may pass through the lower portions of the first dam DAM1 and the second dam DAM2. The first source drain electrode pattern SD1 may be electrically connected to the second source drain electrode pattern SD2 inside the first dam DAM1. The second source drain electrode pattern SD2 may pass through the lower portions of the first dam DAM1 and the second dam DAM2. The second source drain electrode pattern SD2 may be electrically connected to the first source drain electrode pattern SD1 through the contact hole formed in the first planarization layer PLN1 inside the first dam DAM1. The second source drain electrode pattern SD2 may be electrically connected to the cathode electrode CE inside the first dam DAM1. The cathode electrode CE may extend to the display area DA along the side surface of the bank. The cathode electrode CE may be formed of the light emitting element ED in the emission area.

Referring to FIG. 9, in the area A1-A2, the first touch routing line TL1 may overlap the base voltage line VSSL in a portion thereof. In other words, since a portion of the first touch routing line TL1 overlaps the base voltage line VSSL, the space where the first touch routing line TL1 is to be designed may be relatively increased. Accordingly, the first touch routing line TL1 may be easily designed as a dual line. Hereinafter, a cross-sectional view of the area C1-C2 is described.

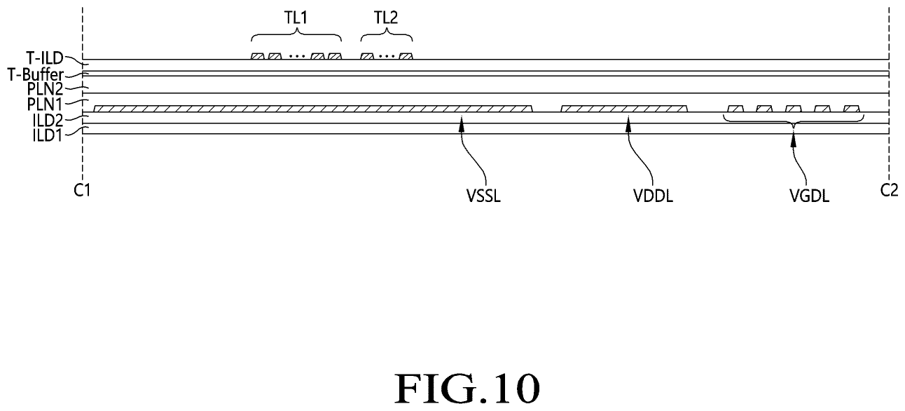

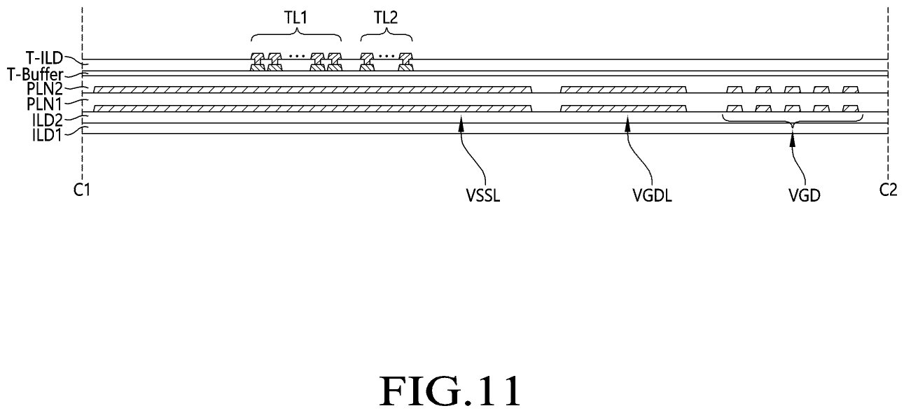

FIGS. 10 and 11 are cross-sectional views of area C1-C2 illustrated in FIG. 7.

Referring to FIG. 10, the base voltage line VSSL may be disposed on the second interlayer insulation film ILD2. Referring to FIG. 10, the base voltage line VSSL may include a first source drain electrode pattern SD1. However, referring to FIG. 11, the base voltage line VSSL may be designed in the dual line form including the first source drain electrode pattern SD1 and the second source drain electrode pattern SD2.

Referring to FIG. 10, the driving voltage line VDDL may be disposed on the second interlayer insulation film ILD2. Referring to FIG. 10, the driving voltage line VDDL may include a first source drain electrode pattern SD1. However, referring to FIG. 11, the driving voltage line VDDL may be designed in the dual line form including the first source drain electrode pattern SD1 and the second source drain electrode pattern SD2.

Referring to FIG. 10, the gate driving voltage line VGDL may be disposed on the second interlayer insulation film ILD2. Referring to FIG. 10, the gate driving voltage line VGDL may include a first source drain electrode pattern SD1. However, referring to FIG. 11, the gate driving voltage line VGDL may be designed in the dual line form including the first source drain electrode pattern SD1 and the second source drain electrode pattern SD2.

Referring to FIG. 10, the base voltage line VSSL, the driving voltage line VDDL, and the gate driving voltage line VGDL may be disposed in the same layer. The driving voltage line VDDL may be disposed between the base voltage line VSSL and the gate driving voltage line VGDL.

Referring to FIG. 10, the touch routing lines TL1 and TL2 may be disposed on the base voltage line VSSL. Referring to FIG. 10, the touch routing lines TL1 and TL2 may be formed in the dual line form. Referring to FIG. 11, according to the selection, the touch routing lines TL1 and TL2 may also be designed in the single line form, and the touch routing lines TL1 and TL2 may include the material of the touch sensor metal TSM.

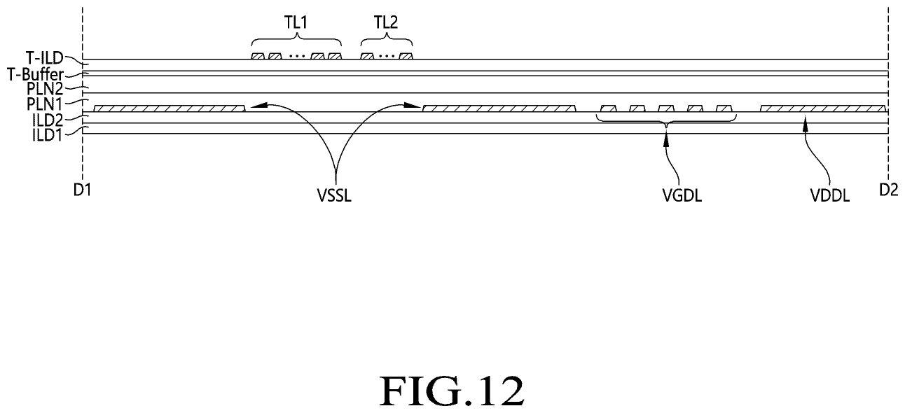

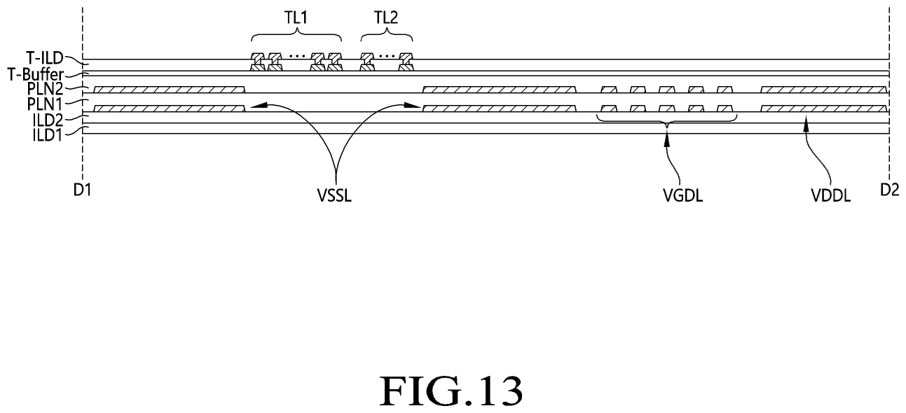

FIGS. 12 and 13 are cross-sectional views of area D1-D2 illustrated in FIG. 7.

Referring to FIG. 12, a portion of the base voltage line VSSL is divided into two sections. The base voltage line VSSL may have a Y shape rotated by 180 degrees, and a portion of the base voltage line VSSL corresponding to the upper end portion of the Y shape is divided.

The gate driving voltage line VGDL may be disposed between the base voltage line VSSL and the driving voltage line VDDL.

Referring to FIG. 12, each of the base voltage line VSSL, the driving voltage line VDDL, and the gate driving voltage line VGDL may be in the single line form. However, referring to FIG. 13, each of the base voltage line VSSL, the driving voltage line VDDL, and the gate driving voltage line VGDL may be designed in the dual line form.

Referring to FIG. 12, the touch routing lines TL1 and TL2 may not overlap the base voltage line VSSL. Referring to FIGS. 10 and 12, the first touch routing line TL1 may overlap the base voltage line VSSL in a portion thereof. In other words, since a portion of the first touch routing line TL1 overlaps the base voltage line VSSL, the space where the first touch routing line TL1 is to be designed may be relatively increased. Accordingly, the first touch routing line TL1 may be easily designed as a dual line. Referring to FIG. 12, the touch routing lines TL1 and TL2 may be formed in a single line form, and referring to FIG. 13, the touch routing lines TL1 and TL2 may be formed in a dual line form.

Implementations of the disclosure described above are briefly described below.

Implementations of the disclosure may provide a display device comprising a substrate including a display area and a non-display area, the non-display area including a pad area, a plurality of touch routing lines extending in a first direction from the pad area toward the display area, and a base voltage line crossing the plurality of touch routing lines and extending in the first direction from an position crossing the plurality of touch routing lines without overlapping the plurality of touch routing lines.

The base voltage line may be branched into two lines at the position crossing the plurality of touch routing lines and extend in the first direction.

The plurality of touch routing lines may be positioned disposed between the two branched lines of the base voltage line.

The plurality of touch routing lines may include a first touch routing line transferring a touch driving signal, and a second touch routing line transferring a touch sensing signal.

The display device may further comprise a first touch electrode disposed in the display area and electrically connected to the first touch routing line, and a second touch electrode disposed in the display area and electrically connected to the second touch routing line.

The display device may further comprise a touch sensing circuit supplying the touch driving signal to the first touch routing line and receiving the touch sensing signal through the second touch routing line.

The display device may further comprise a plurality of subpixels disposed in the display area and receiving a base voltage through the base voltage line.

The substrate may further include a bending area positioned between the display area and the pad area, and the plurality of touch routing lines may not overlap the base voltage line in the bending area.

The display device may further comprise a plurality of gate driving voltage lines extending in the first direction without overlapping the plurality of touch routing lines.

The plurality of gate driving voltage lines may not overlap the base voltage line.

The plurality of touch routing lines may at least partially include a dual line form including two metal layers disposed with an insulation layer interposed therebetween.

The substrate may further include a bending area positioned between the display area and the pad area. The plurality of touch routing lines may have a single line form different from the dual line form.

The plurality of touch routing lines may not overlap the base voltage line in the bending area.

In an area between the display area and the bending area, the plurality of touch routing lines may have the dual line form and may not overlap the base voltage line.

The substrate may further include a bending area positioned between the display area and the pad area. The base voltage line may include a first metal material extending from the pad area to the bending area, and a second metal material disposed in the bending area and electrically connected to the first metal material.

The base voltage line may have a plate shape.

Implementations of the disclosure may provide a display device comprising a substrate including a display area and a pad area of a non-display area, a first metal pattern disposed on the substrate and extending in a first direction from the pad area toward the display area, to be branched into two lines, and a second metal pattern disposed on the first metal pattern and extending in the first direction while at least partially overlapping the first metal pattern.

The second metal pattern may extend toward the display area without overlapping the first metal pattern after overlapping the first metal pattern.

The substrate may further include a bending area between the display area and the pad area. The second metal pattern may have a single line form in the bending area, and the second metal pattern may extend in a dual line form from the bending area to the display area.

the second metal pattern may not overlap the first metal pattern in the bending area, and at least a portion of the second metal pattern may extend from the bending area to the display area without overlapping the first metal pattern.

The above description has been presented to enable any person skilled in the art to make and use the technical idea of the disclosure, and has been provided in the context of a particular application and its requirements. Various modifications, additions and substitutions to the described implementations will be readily apparent to those skilled in the art, and the general principles defined herein may be applied to other implementations and applications without departing from the spirit and scope of the disclosure. The above description and the accompanying drawings provide an example of the technical idea of the disclosure for illustrative purposes. That is, the disclosed implementations are intended to illustrate the scope of the technical idea of the disclosure.

What is claimed:

1. A display device, comprising:
a substrate including a display area and a non-display area, the non-display area including a pad area;
a plurality of touch routing lines disposed in the non-display area and extending in a first direction from the pad area toward the display area; and
a base voltage line disposed in the non-display area, the base voltage line comprising a trunk portion and two branched portions extending from the trunk portion,
wherein the plurality of touch routing lines cross the trunk portion and extend between the two branched portions without overlapping the two branched portions.

2. The display device of claim 1, wherein the plurality of touch routing lines comprise a first touch routing line configured to transfer a touch driving signal and a second touch routing line configured to transfer a touch sensing signal.

3. The display device of claim 2, further comprising:
a first touch electrode disposed in the display area and electrically connected to the first touch routing line; and
a second touch electrode disposed in the display area and electrically connected to the second touch routing line.

4. The display device of claim 3, further comprising a touch sensing circuit configured to supply the touch driving signal to the first touch routing line and receive the touch sensing signal from the second touch routing line.

5. The display device of claim 1, further comprising a plurality of subpixels disposed in the display area, wherein each of the plurality of subpixels is electrically connected to the base voltage line to receive a base voltage.

6. The display device of claim 1, wherein:
the non-display area further comprises a bending area between the pad area and the display area; and
the plurality of touch routing lines and the two branched portions of the base voltage line extend through the bending area.

7. The display device of claim 1, further comprising a plurality of gate driving voltage lines disposed in the non-display area and extending in the first direction, wherein the plurality of gate driving voltage lines do not overlap the plurality of touch routing lines.

8. The display device of claim 7, wherein the plurality of gate driving voltage lines do not overlap the base voltage line.

9. The display device of claim 1, wherein at least one of the plurality of touch routing lines comprises a dual line structure including two metal layers separated by an insulation layer.

10. The display device of claim 6, wherein at least one of the plurality of touch routing lines comprises a dual-line structure in a first portion of the non-display area and a single-line structure in the bending area.

11. The display device of claim 10, wherein the dual-line structure is located in a region between the display area and the bending area.

12. The display device of claim 6, wherein the base voltage line comprises:
a first metal material extending from the pad area to the bending area; and
a second metal material disposed within the bending area and electrically connected to the first metal material.

13. The display device of claim 1, wherein the trunk portion of the base voltage line is formed as a single continuous conductor having a width substantially greater than a width of any one of the plurality of touch routing lines.

14. A display device, comprising:
a substrate including a display area and a non-display area having a pad area;
a first metal pattern disposed in the non-display area and extending in a first direction from the pad area toward the display area; and
a plurality of second metal patterns disposed on the substrate and extending in the first direction from the pad area toward the display area,
wherein the first metal pattern crosses the plurality of second metal patterns at a crossing position and subsequently branches into first and second branched portions, and
wherein, in a region extending in the first direction from the crossing position, the plurality of second metal patterns are disposed between the first and second branched portions of the first metal pattern without overlapping the first and second branched portions.

15. The display device of claim 14, wherein the first metal pattern is a base voltage line and the plurality of second metal patterns are a plurality of touch routing lines.

16. The display device of claim 15, wherein:
the substrate further comprises a bending area positioned between the display area and the pad area, and
at least one of the plurality of touch routing lines has a single-line structure within the bending area and a dual-line structure in a region between the bending area and the display area.

17. The display device of claim 16, wherein the dual-line structure comprises a touch sensor metal layer and a bridge metal layer, with an insulating layer disposed between the touch sensor metal layer and the bridge metal layer.

18. A display device, comprising:
a substrate including a display area and a non-display area, the non-display area including a pad area;
a plurality of touch routing lines disposed in the non-display area and extending in a first direction from the pad area toward the display area; and
a base voltage line disposed in the non-display area, the base voltage line extending in the first direction from the pad area toward the display area,
wherein the base voltage line configured to cross the plurality of touch routing lines at a crossing position and subsequently branches into first and second branched portions,
wherein, in a region extending in the first direction from the crossing position, the plurality of touch routing lines are disposed between the first and second branched portions of the base voltage line without overlapping the first and second branched portions.

19. The display device of claim 18, wherein:
the non-display area further comprises a bending area between the pad area and the display area; and
the plurality of touch routing lines and the first and second branched portions of the base voltage line extend through the bending area.

20. The display device of claim 18, further comprising a plurality of gate driving voltage lines disposed in the non-display area and extending in the first direction, wherein the plurality of gate driving voltage lines do not overlap the plurality of touch routing lines.
